(19) United States
(12) Patent Application Publication
(10) Pub. No.: US 2023/0167581 A1
(43) Pub. Date: Jun. 1, 2023

(54) WAFER EDGE TEMPERATURE CORRECTION IN BATCH THERMAL PROCESS CHAMBER

(71) Applicant: Applied Materials, Inc., Santa Clara, CA (US)

(72) Inventors: Kartik Bhupendra SHAH, Saratoga, CA (US); Schubert S. CHU, San Francisco, CA (US); Adel George TANNOUS, Santa Clara, CA (US); Ala MORADIAN, Sunnyvale, CA (US); Nyi Oo MYO, San Jose, CA (US); Surajit KUMAR, San Jose, CA (US); Zuoming ZHU, Sunnyvale, CA (US); Brian Hayes BURROWS, San Jose, CA (US); Vishwas Kumar PANDEY, Madhya Pradesh (IN); Shu-Kwan LAU, Sunnyvale, CA (US); Srinivasa RANGAPPA, Bangalore (IN)

(21) Appl. No.: 17/919,896

(22) PCT Filed: Jul. 16, 2021
(86) PCT No.: PCT/US2021/042065

§ 371 Date: Oct. 19, 2022

(30) Foreign Application Priority Data
Aug. 3, 2020 (IN) 202041033207

(51) Int. Cl. C30B 25/10; H01L 21/687; H01L 21/67; C30B 25/18; C30B 25/08; C23C 16/02

(52) U.S. Cl. CPC C30B 25/105; H01L 21/68771; H01L 21/68764; H01L 21/67248; H01L 21/68757; C30B 25/186; C30B 25/08; C23C 16/0209; C23C 16/0227

(57) ABSTRACT

A process kit for use in a processing chamber includes an outer liner, an inner liner configured to be in fluid communication with a gas injection assembly and a gas exhaust assembly of a processing chamber, a first ring reflector disposed between the outer liner and the inner liner, a top plate and a bottom plate attached to an inner surface of the inner liner, the top plate and the bottom plate forming an enclosure together with the inner liner, a cassette disposed within the enclosure, the cassette comprising a plurality of shelves configured to retain a plurality of substrates thereon, and an edge temperature correcting element disposed between the inner liner and the first ring reflector.

### BACKGROUND

### Field

Examples described herein generally relate to the field of semiconductor processing, and more specifically, to pre-epitaxial baking of wafers.

### Description of the Related Art

In conventional semiconductor fabrication, wafers are pre-cleaned to remove contaminants, such as oxides, prior to thin film growth thereon by epitaxial processes. Pre-cleaning of wafers is performed by baking the wafers in a hydrogen atmosphere either in a single wafer epitaxial (Epi) chamber or in a furnace. Single wafer Epi chambers have been designed to provide uniform temperature distribution over a wafer disposed within a processing volume and precise control of gas flow over the wafer. However, a single wafer Epi chamber processes one wafer at a time, and thus may not provide required throughputs in fabrication processes. Furnaces enable batch processing of multiple wafers. However, furnaces do not provide uniform temperature distribution over each wafer and/or between wafers disposed in a processing volume, and thus may not provide required qualities in fabricated devices. In particular, heat loss in the vicinity of wafer edges causes highly non-uniform temperature distribution over each wafer.

Therefore, there is need for a process and processing equipment that is able to perform batch multi-wafer process while reducing heat loss in the vicinity of wafer edges to provide uniform temperature distribution over a wafer.

### SUMMARY

Embodiments of the disclosure include a process kit for use in a processing chamber. The process kit includes an outer liner, an inner liner having a plurality of first inlet holes disposed on an injection side of the inner liner and configured to be in fluid communication with a gas injection assembly of a processing chamber, and a plurality of first outlet holes disposed on an exhaust side of the inner liner and configured to be in fluid communication with a gas exhaust assembly of the processing chamber, a first ring reflector disposed between the outer liner and the inner liner, a top plate and a bottom plate attached to an inner surface of the inner liner, the top plate and the bottom plate forming an enclosure together with the inner liner, a cassette disposed within the enclosure, the cassette comprising a plurality of shelves configured to retain a plurality of substrates thereon, and an edge temperature correcting element disposed between the inner liner and the first ring reflector.

Embodiments of the disclosure also include a processing chamber. The processing chamber includes a housing structure having a first side wall and a second side wall opposite the first side wall in a first direction, a gas injection assembly coupled to the first side wall, a gas exhaust assembly coupled to the second side wall, a quartz chamber disposed within the housing structure, a process kit disposed within the quartz chamber, the process kit comprising a cassette having a plurality of shelves configured to retain a plurality of substrates thereon, a plurality of upper lamp modules disposed on a first side of the quartz chamber and configured to provide radiative heat to the plurality of substrates, a plurality of lower lamp modules disposed on a second side of the quartz chamber opposite the first side in a second direction perpendicular to the first direction and configured to provide radiative heat to the plurality of substrates, and a lift-rotation mechanism configured to move the cassette in the second direction and rotate the cassette about the second direction. The process kit further includes an outer liner, an inner liner having a plurality of first inlet holes disposed on an injection side of the inner liner and configured to be in fluid communication with the gas injection assembly, and a plurality of first outlet holes disposed on an exhaust side of the inner liner and configured to be in fluid communication with the gas exhaust assembly, a first ring reflector disposed between the outer liner and the inner liner, a top plate and a bottom plate attached to an inner surface of the inner liner, the top plate and the bottom plate forming an enclosure together with the inner liner, the cassette being disposed within the enclosure, and an edge temperature correcting element disposed between the inner liner and the first ring reflector.

Embodiments of the disclosure further include a processing system. The processing system includes a processing chamber including a housing structure having a first side wall and a second side wall opposite the first side wall in a first direction, a gas injection assembly coupled to the first side wall, a gas exhaust assembly coupled to the second side wall, a quartz chamber disposed within the housing structure, a process kit disposed within the quartz chamber, the process kit including a cassette having a plurality of shelves configured to retain a plurality of substrates thereon, an outer liner, an inner liner having a plurality of first inlet holes disposed on an injection side of the inner liner and configured to be in fluid communication with the gas injection assembly, and a plurality of first outlet holes disposed on an exhaust side of the inner liner and configured to be in fluid communication with the gas exhaust assembly, and a first ring reflector disposed between the outer liner and the inner liner, a top plate and a bottom plate attached to an inner surface of the inner liner, the top plate and the bottom plate forming an enclosure together with the inner liner, the cassette being disposed within the enclosure, and an edge temperature correcting element disposed between the inner liner and the first ring reflector, a plurality of upper lamp modules disposed on a first side of the quartz chamber and configured to provide radiative heat to the plurality of substrates, a plurality of lower lamp modules disposed on a second side of the quartz chamber opposite the first side in a second direction perpendicular to the first direction and configured to provide radiative heat to the plurality of substrates, a lift-rotation mechanism configured to move the cassette in the second direction and rotate the cassette about the second direction, and a transfer robot configured to transfer the plurality of substrates into and from the process kit disposed in the processing chamber.

### BRIEF DESCRIPTION OF THE DRAWINGS

So that the manner in which the above recited features of the present disclosure can be understood in detail, a more particular description, briefly summarized above, may be had by reference to examples, some of which are illustrated in the appended drawings. It is to be noted, however, that the appended drawings illustrate only some examples and are therefore not to be considered limiting of the scope of this disclosure, for the disclosure may admit to other equally effective examples.

FIG. 1 is a schematic top-view diagram of an example of a batch multi-chamber processing system according to one or more embodiments.

FIG. 2 is a schematic cross-sectional view of an exemplary processing chamber that may be used to perform batch multi-wafer cleaning processes according to one or more embodiments.

FIG. 3 is a schematic cross-sectional view of a process kit according to one embodiment.

FIG. 4 is a schematic cross-sectional view of a process kit according to one embodiment.

FIG. 5 is a schematic cross-sectional view of a process kit according to one embodiment.

To facilitate understanding, identical reference numerals have been used, wherever possible, to designate identical elements that are common to the figures.

### DETAILED DESCRIPTION

Generally, examples described herein generally relate to the field of semiconductor processing, and more specifically, to pre-epitaxial baking of wafers.

Some examples described herein provide a multi-wafer batch processing system where multiple substrates are pre-cleaned to remove contaminants, such as oxides, prior to thin film growth thereon by epitaxial processes by baking the substrates in a hydrogen atmosphere in an epitaxial (Epi) chamber while uniform temperature distribution is maintained over a substrate and between substrates disposed within a processing volume. Thus, the multi-wafer batch processing system may provide improved qualities and throughputs in fabricated devices.

Various different examples are described below. Although multiple features of different examples may be described together in a process flow or system, the multiple features can each be implemented separately or individually and/or in a different process flow or different system.

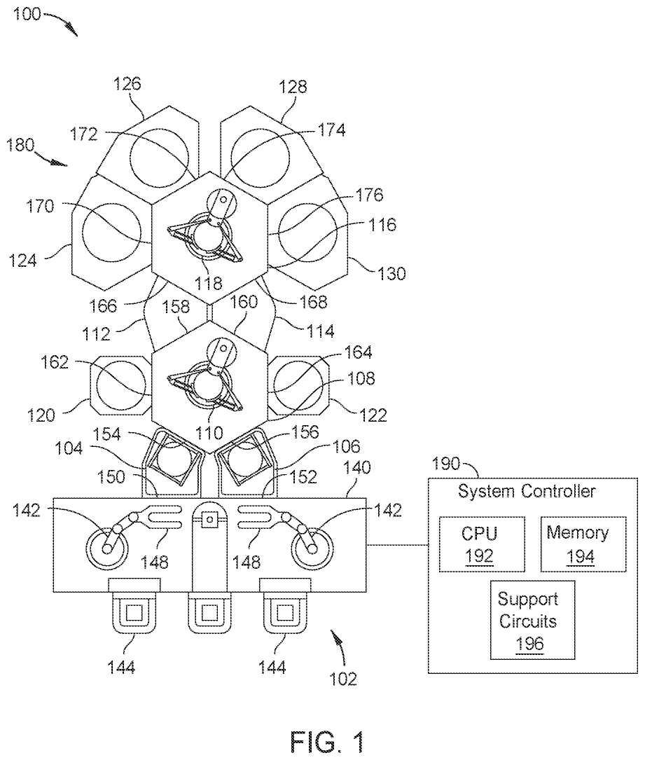

FIG. 1 is a schematic top-view diagram of an example of a processing system 100 according to one or more embodiments. The processing system 100 generally includes a factory interface 102, load lock chambers 104, 106, transfer chambers 108, 116 with respective transfer robots 110, 118, holding chambers 112, 114, and processing chambers 120, 122, 124, 126, 128, 130. As detailed herein, substrates in the processing system 100 can be processed in and transferred between the various chambers without being exposed to an ambient environment exterior to the processing system 100. For example, substrates can be processed in and transferred between the various chambers in a low pressure (e.g., less than or equal to about 300 Torr) or vacuum environment without breaking the low pressure or vacuum environment between various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, Calif. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of substrates. The docking station 140 is configured to accept one or more front opening unified pods (FOUPs) 144. In some examples, each factory interface robot 142 generally comprises a blade 148 disposed on one end of the respective factory interface robot 142 configured to transfer substrates from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 112, 114 and respective ports 162, 164 coupled to processing chambers 120, 122. Similarly, the transfer chamber 116 has respective ports 166, 168 coupled to the holding chambers 112, 114 and respective ports 170, 172, 174, 176 coupled to processing chambers 124, 126, 128, 130. The ports 154, 156, 158, 160, 162, 164, 166, 168, 170, 172, 174, 176 can be, for example, slit openings with slit valves for passing substrates therethrough by the transfer robots 110, 118 and for providing a seal between respective chambers to prevent a gas from passing between the respective chambers. Generally, any port is open for transferring a substrate therethrough; otherwise, the port is closed.

The load lock chambers 104, 106, transfer chambers 108, 116, holding chambers 112, 114, and processing chambers 120, 122, 124, 126, 128, 130 may be fluidly coupled to a gas and pressure control system (not shown). The gas and pressure control system can include one or more gas pumps (e.g., turbo pumps, cryo-pumps, roughing pumps, etc.), gas sources, various valves, and conduits fluidly coupled to the various chambers. In operation, a factory interface robot 142 transfers a substrate from a FOUP 144 through a port 150 or 152 to a load lock chamber 104 or 106. The gas and pressure control system then pumps down the load lock chamber 104 or 106. The gas and pressure control system further maintains the transfer chambers 108, 116 and holding chambers 112, 114 with an interior low pressure or vacuum environment (which may include an inert gas). Hence, the pumping down of the load lock chamber 104 or 106 facilitates passing the substrate between e.g., the atmospheric environment of the factory interface 102 and the low pressure or vacuum environment of the transfer chamber 108.

With the substrate in the load lock chamber 104 or 106 that has been pumped down, the transfer robot 110 transfers the substrate from the load lock chamber 104 or 106 into the transfer chamber 108 through the port 154 or 156. The transfer robot 110 is then capable of transferring the substrate to and/or between any of the processing chambers 120, 122 through the respective ports 162, 164 for processing and the holding chambers 112, 114 through the respective ports 158, 160 for holding to await further transfer. Similarly, the transfer robot 118 is capable of accessing the substrate in the holding chamber 112 or 114 through the port 166 or 168 and is capable of transferring the substrate to and/or between any of the processing chambers 124, 126, 128, 130 through the respective ports 170, 172, 174, 176 for processing and the holding chambers 112, 114 through the respective ports 166, 168 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 122 can be capable of performing a cleaning process; the processing chamber 120 can be capable of performing an etch process; and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 112, 114, 116, 120, 122, 124, 126, 128, 130 of the processing system 100 or by controlling controllers associated with the chambers 104, 106, 108, 112, 114, 116, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular processing chamber) as, e.g., a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 116 and the holding chambers 112, 114. In other examples, more or fewer transfer chambers (e.g., one transfer chamber) and/or more or fewer holding chambers (e.g., no holding chambers) may be implemented as a transfer apparatus in a processing system.

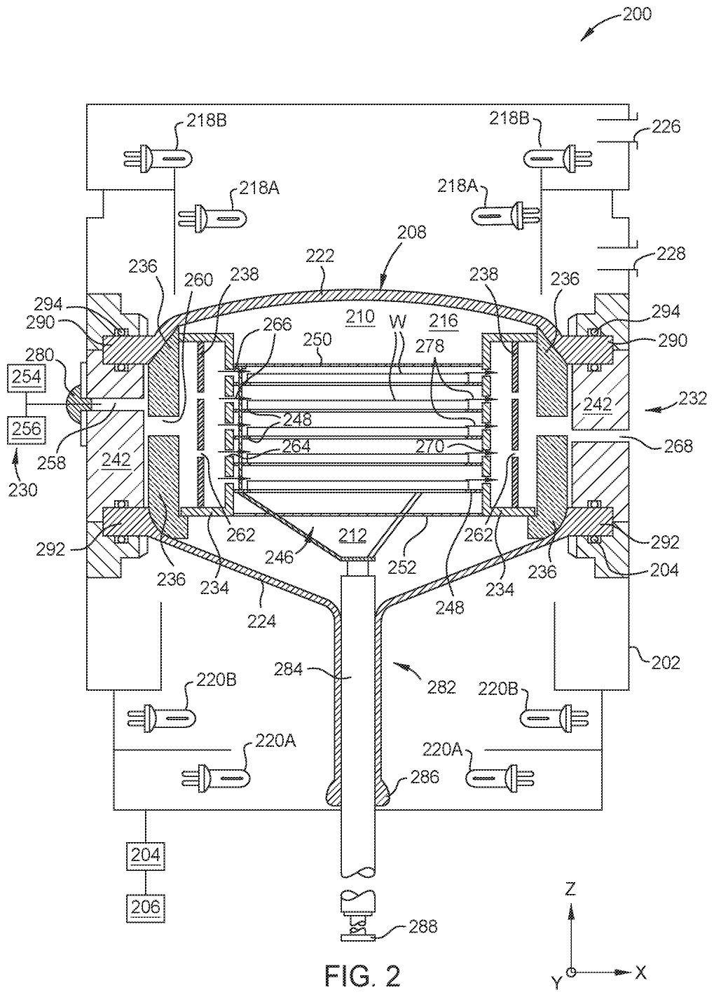

FIG. 2 is a schematic cross-sectional view of an exemplary processing chamber 200 that may be used to perform batch multi-wafer cleaning processes, such as a baking process in hydrogen atmosphere at a temperature of about 800° C. The processing chamber 200 may be any one of processing chambers 120, 122, 124, 126, 128, 130 from FIG. 1. Non-limiting examples of the suitable processing chambers that may be modified according to embodiments disclosed herein may include the RP EPI reactor, Elvis chamber, and Lennon chamber, which are all commercially available from Applied Materials, Inc. of Santa Clara, Calif. The processing chambers 200 may be added to a CENTURA® integrated processing system available from Applied Materials, Inc., of Santa Clara, Calif. While the processing chamber 200 is described below to be utilized to practice various embodiments described herein, other semiconductor processing chambers from different manufacturers may also be used to practice the embodiment described in this disclosure.

The processing chamber 200 includes a housing structure 202, a support system 204, and a controller 206. The housing structure 202 is made of a process resistant material, such as aluminum or stainless steel. The housing structure 202 encloses various function elements of the processing chamber 200, such as a quartz chamber 208, which includes an upper portion 210 and a lower portion 212. A process kit 214 is adapted to receive multiple substrates W within the quartz chamber 208, in which a processing volume 216 is contained.

As used herein, the term “substrate” refers to a layer of material that serves as a basis for subsequent processing operations and includes a surface to be disposed for forming thin films thereon. The substrate may be a silicon wafer, silicon oxide, strained silicon, silicon germanium, doped or undoped polysilicon, doped or undoped silicon wafers, patterned or non-patterned wafers silicon on insulator (SOI), carbon doped silicon oxides, silicon nitride, indium phosphide, germanium, gallium arsenide, gallium nitride, quartz, fused silica, glass, or sapphire. Moreover, the substrate is not limited to any particular size or shape. The substrate can be a round wafer having a 200 mm diameter, a 300 mm diameter or other diameters, such as 450 mm, among others. The substrate W can also be any polygonal, square, rectangular, curved or otherwise non-circular workpiece, such as a polygonal glass substrate.

Heating of the substrates W may be provided by radiation sources, such as one or more upper lamp modules 218A, 218B above the quartz chamber 208 in the Z-direction and one or more lower lamp modules 220A, 220B below the quartz chamber 208 in the Z-direction. In one embodiment, the upper lamp modules 218A, 218B and the lower lamp modules 220A, 220B are infrared lamps. Radiation from the upper lamp modules 218A, 218B and the lower lamp modules 220A, 220B travels through an upper quartz window 222 in the upper portion 210, and through a lower quartz window 224 in the lower portion 212. In some embodiments, cooling gases for the upper portion 210 can enter through an inlet 226 and exit through an outlet 228.

One or more gases are provided to the processing volume 216 of the quartz chamber 208 by a gas injection assembly 230, and processing byproducts are removed from the processing volume 216 by a gas exhaust assembly 232, which is typically in communication with a vacuum source (not shown).

The process kit 214 further includes multiple cylindrical liners, an inner liner 234 and an outer liner 236 that shield the processing volume 216 from side walls 242 of the housing structure 202. The inner liner 234 includes one or more inlet holes 264 on a side facing the gas injection assembly 230 in the −X direction (referred to as an “injection side” hereinafter) and one or more outlet holes 270 an a side facing the gas exhaust assembly 232 in the +X direction (referred to as an “exhaust side” hereinafter). The outer liner 236 includes one or more inlet holes 260 on the injection side and one or more outlet holes 272 on the exhaust side. Between the inner liner 234 and the outer liner 236, a ring reflector 238 is disposed. The ring reflector 238 includes one or more inlet holes 262 on the injection side and one or more outlet holes 274 on the exhaust side. The ring reflector 238 is generally of a cylindrical tubular structure with a reflective surface facing the inner liner 234. The reflective surface of the ring reflector 238 reflects radiant heat from the inner liner 234 and confines the heat within the inner liner 234 that could otherwise escape the inner liner 234. The ring reflector 238 is formed of opaque quartz or silicon-carbide (SiC) coated graphite. In some embodiments, an inner surface of the ring reflector 238 facing the inner liner 234 is coated with a highly reflective material, such as gold, to prevent heat loss. In some other embodiments, the inner surface of the ring reflector 238 facing the inner liner 234 is coated with a reflective material, such as silica, for example, Heraeus Reflective Coating, HRC®. The inner liner 234 acts as cylinder walls to the processing volume 216 that houses a cassette 246 having a plurality of shelves 248 (e.g., five shelves are shown in FIG. 2) to retain multiple substrates W for a batch multi-wafer process. The shelves 248 are interleaved between the substrates W retained in the cassette 246 so that a gap exists between the shelves 248 and the substrates W to allow efficient mechanical transfer of the substrates W to and from the shelves 248. A substrate W may be transferred into and from the processing volume 216 by a transfer robot, such as the transfer robots 110, 118 shown in FIG. 1, via a slip opening (not shown) formed in the outer liner 236 on a front side facing the —Y direction. In some embodiments, substrates W are transferred into and from the cassette 246 one by one. In some embodiments, the slit opening of the outer liner 236 is openable and closable by using a slit valve (not shown).

The process kit 214 further includes a top plate 250 and a bottom plate 252 that are attached to an inner surface of the inner liner 234 and enclose the cylindrical processing volume 216 within the process kit 214. The top plate 250 and the bottom plate 252 are disposed at a sufficient distance apart from the shelves 248 to allow gas flow over substrates W retained in the shelves 248.

The inner liner 234 is formed of clear quartz, silicon-carbide (SiC) coated graphite, graphite, or silicon carbide (SiC). The top plate 250 and the bottom plate 252 are formed of clear quartz, opaque quartz, silicon-carbide (SiC) coated graphite, graphite, silicon carbide (SiC), or silicon (Si), such that heat loss from the processing volume 216 through the top plate 250 and/or the bottom plate 252 is reduced. The shelves 248 of the cassette 246 disposed within the processing volume 216 are also formed of material, such as silicon-carbide (SiC) coated graphite, graphite, or silicon carbide (SiC). The outer liner 236 is formed of material having a high reflectivity, such as opaque quartz, and further reduce heat loss from the processing volume 216 within the process kit 214. In some embodiments, the outer liner 236 is formed in a hollow structure, in which vacuum between an inner surface of the outer liner 236 facing the inner liner 234 and an outer surface of the outer liner 236 facing the side walls 242 of the housing structure 202 reduces heat conduction through the outer liner 236.

The gases can be injected to the processing volume 216 from a first gas source 254, such as hydrogen (H₂), nitrogen (N₂), or any carrier gas, along with or without a second gas source 256 of the gas injection assembly 230 through the inlet holes 264 formed in the inner liner 234. The inlet holes 264 in the inner liner 234 are in fluid communication with the first gas source 254 and the second gas source 256 via an injection plenum 258 formed in the side wall 242, the inlet holes 260 formed in the outer liner 236, and the inlet holes 262 formed in the ring reflector 238. The injected gases form gas flow along a laminar flow path 266. The inlet holes 260, 262, 264 may be configured to provide gas flows with varied parameters, such as velocity, density, or composition.

The gases along the flow path 266 are configured to flow across the processing volume 216 into an exhaust plenum 268 formed in the side wall 242 to be exhausted by the gas exhaust assembly 232 from the processing volume 216. The gas exhaust assembly 232 is in fluid communication with the outlet holes 270 formed in the inner liner 234 via the outlet holes 272 formed in the outer liner 236, the outlet holes 274 formed in the ring reflector 238, and the exhaust plenum 268, culminating the gases in an exhaust flow path 278. The exhaust plenum 268 is coupled to an exhaust or vacuum pump (not shown). At least the injection plenum 258 may be supported by an inject cap 280. In some embodiments, the processing chamber 200 is adapted to supply one or more liquids for processes, such as deposition and etch processes. Furthermore, although only two gas sources 254, 256 are shown in FIG. 2, the processing chamber 200 could be adapted to accommodate as many fluid connections as needed for the processes executed in the processing chamber 200.

The support system 204 includes components used to execute and monitor pre-determined processes in the processing chamber 200. A controller 206 is coupled to the support system 204 and is adapted to control the processing chamber 200 and support system 204.

The processing chamber 200 includes a lift-rotation mechanism 282 positioned in the lower portion 212 of the housing structure 202. The lift-rotation mechanism 282 includes a shaft 284 positioned within a shroud 286 to which lift pins (not shown) disposed through openings (not labeled) formed in the shelves 248 of the process kit 214 is coupled. The shaft 284 is movable vertically in the Z-direction to allow loading substrates W into and unloading substrates W from the shelves 248 through a slit opening (not shown) in the inner liner 234 and a slit opening not shown in the outer liner 236 by a transfer robot, such as the transfer robots 110, 118 shown in FIG. 1. The shaft 284 is also rotatable in order to facilitate the rotation of substrates W disposed within the process kit 214 in the X-Y plane during processing. Rotation of the shaft 284 is facilitated by an actuator 288 coupled to the shaft 284. The shroud 286 is generally fixed in position, and therefore, does not rotate during processing.

The quartz chamber 208 includes peripheral flanges 290, 292 that are attached to and vacuum sealed to the side walls 242 of the housing structure 202 using O-rings 294. The peripheral flanges 290, 292 may all be formed from an opaque quartz to protect O-rings 294 from being directly exposed to the heat radiation. The peripheral flange 290 may be formed of an optically transparent material such as quartz.

In the example embodiments described herein, the process kit 214 includes an edge temperature correcting element disposed between the inner liner 234 and the ring reflector 238 that improves temperature uniformity over each substrate W retained in the shelves 248 in the processing volume 216 by compensating for or reducing heat loss from the processing volume 216 in the vicinity of edges of the substrates W.

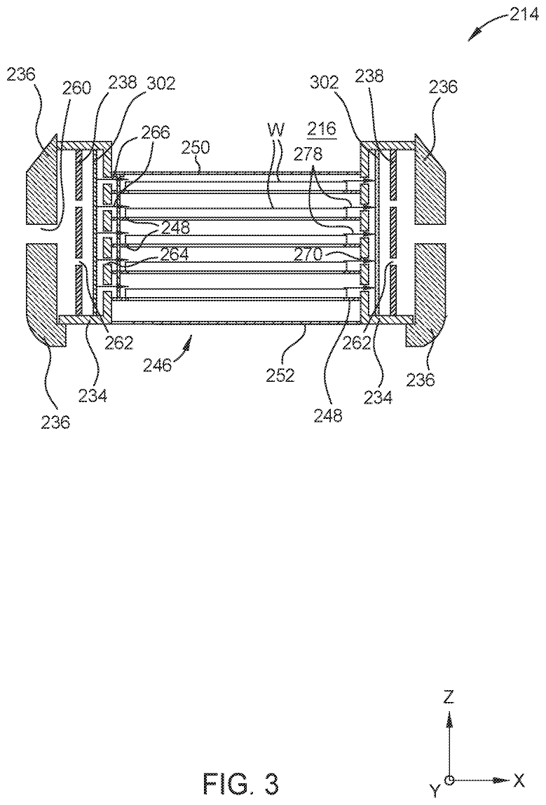

FIG. 3 is a schematic cross-sectional view of the process kit 214 according to one embodiment. In the example embodiment shown in FIG. 3, the edge temperature correcting element is two heaters 302 that surround the inner liner 234. One heater 302 is disposed on the injection side and the other heater 302 is disposed on the exhaust side. The heaters 302 may be adapted to heat the substrates W retained in the shelves 248 additionally to the upper lamp modules 218A, 218B and the lower lamp modules 220A, 220B and compensate for heat losses from the processing volume 216 in the vicinity of the inner liner 234.

The heaters 302 can be a graphite heater of a cylindrical shape. In some embodiments, the heaters 302 are formed of silicon-carbide (SiC) coated graphite. One or more terminals (not shown) are provided to support the heaters 302. The heaters 302 each include a plurality of slits extending in the Z-direction, allowing efficient generation of heat generation and flow of the gases through the inner liner 234. Spatial arrangement and sizes of the plurality of slits can be adjusted to provide desired temperature gradient in the Z-direction. In one example, the heaters 302 each have a length in the Z-direction of between about 1,000 mm and about 3,500 mm, a height of between about 25 mm and about 125 mm, a thickness of between about 4 mm and about 8 mm, and a width of between about 4 mm and about 12 mm. The heaters 302 can heat the substrates W retained in the shelves 248 up to about 1200° C. In some embodiments, temperatures of the substrates W in the vicinity of the inner liner 234 can be tuned at a desired temperature by adjustment of power delivered to the heaters 302.

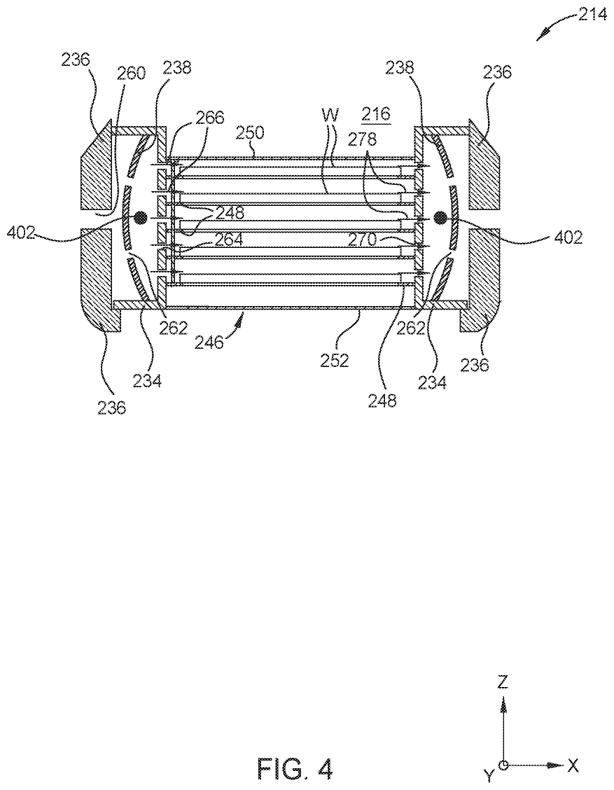

FIG. 4 is a schematic cross-sectional view of the process kit 214 according to one embodiment. In the example embodiment shown in FIG. 4, the edge temperature correcting element is a heater 402 that encircles the inner liner 234. The heater 402 may be adapted to heat the substrates W retained in the shelves 248 additionally to the upper lamp modules 218A, 2186 and the lower lamp modules 220A, 220B and compensate for heat losses from the processing volume 216 in the vicinity of the inner liner 234.

The heater 402 can be a lamp, for example a lamp of a toroidal shape, disposed between the inner liner 234 and the ring reflector 238, and provide radiant energy to the substrates W retained in the shelves 248, leading to efficient heating with a short ramp-up and ramp-down time. Due to the toroidal shape of the lamp encircling the inner liner 234, the heater 402 allows flow of the gases between the inlet holes 260 of the outer liner 236 and the outlet holes 272 of the outer liner without obstruction. In some embodiments, the heater 402 is a toroidal bulb having a filament disposed therein.

In some embodiments, the ring reflector 238 is curved to create a sufficient space to accommodate the heater 402 of a toroidal shape between the inner liner 234 and the ring reflector 238.

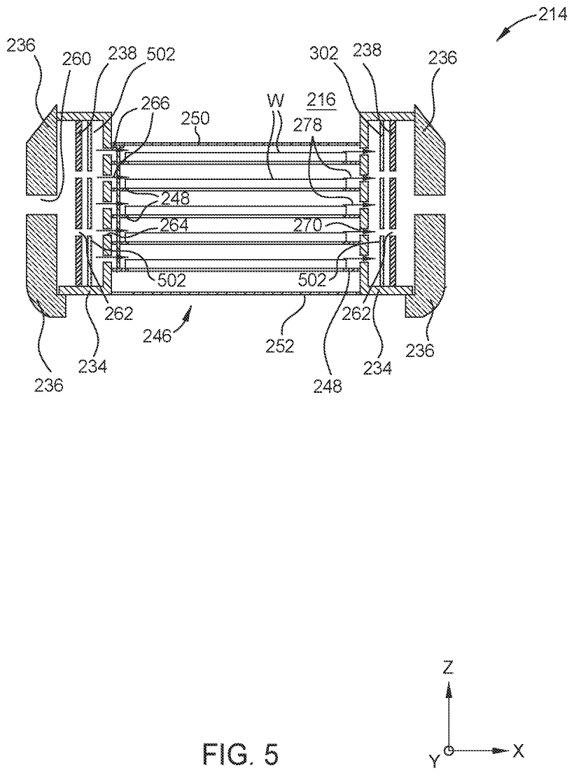

FIG. 5 is a schematic cross-sectional view of the process kit 214 according to one embodiment. In the example embodiment shown in FIG. 5, the edge temperature correcting element is one or more additional ring reflector 502 that surround the inner liner 234. The one or more additional ring reflector 502 may be formed of the same material as the ring reflector 238 or a different material, and are adapted to act as a radiation/conduction heat shield within the inner liner 234, thus reducing heat loss from the processing volume 216 in the vicinity of the inner liner 234. The additional ring reflector 506 also includes one or more inlet holes (not labeled) on the injection side and one or more outlet holes (not labeled), allowing flow of the gases through the inner liner 234.

In examples described herein, a multi-wafer batch processing system is shown where multiple substrates are pre-cleaned to remove contaminants, such as oxides, prior to thin film growth thereon by epitaxial processes by baking the substrates in a hydrogen atmosphere in an epitaxial (Epi) chamber while uniform temperature distribution is maintained over a substrate, in particular in the vicinity of edges of the substrate, disposed within a processing volume. Thus, the multi-wafer batch processing system may provide required qualities and throughputs in fabricated devices.

While the foregoing is directed to various examples of the present disclosure, other and further examples may be devised without departing from the basic scope thereof, and the scope thereof is determined by the claims that follow.

1. A process kit for use in a processing chamber, the process kit comprising:
an inner liner having:
a plurality of first inlet holes disposed on an injection side of the inner liner and configured to be in fluid communication with a gas injection assembly of a processing chamber; and
a plurality of first outlet holes disposed on an exhaust side of the inner liner and configured to be in fluid communication with a gas exhaust assembly of the processing chamber;
a top plate and a bottom plate attached to an inner surface of the inner liner, the top plate and the bottom plate forming an enclosure together with the inner liner;
a cassette disposed within the enclosure, the cassette comprising a plurality of shelves configured to retain a plurality of substrates thereon;
a first ring reflector disposed outside of the inner liner; and
an edge temperature correcting element disposed between the inner liner and the first ring reflector.

2. The process kit of claim 1, further comprising:
an outer liner outside of the first ring reflector, wherein
the outer liner comprises material selected from opaque quartz and silicon-carbide (SiC) coated graphite.

3. The process kit of claim 1, wherein
the inner liner comprises material selected from clear quartz and silicon-carbide (SiC) coated graphite, and
the top plate and the bottom plate comprise material selected from clear quartz, opaque quarts, silicon-carbide (SiC) coated graphite.

4. The process kit of claim 1, wherein
the first ring reflector comprises material selected from opaque quartz or silicon-carbide (SiC) coated graphite, and
the plurality of shelves comprises silicon-carbide (SiC) coated graphite.

5. The process kit of claim 1, wherein the edge temperature correcting element comprises two graphite heaters surrounding the inner liner.

6. The process kit of claim 1, wherein the edge temperature correcting element comprises a lamp between the inner liner and the first ring reflector.

7. The process kit of claim 1, wherein the edge temperature correcting element comprises a toroidal lamp encircling the inner liner.

8. The process kit of claim 1, wherein
the edge temperature correcting element comprises a second ring reflector surrounding the inner liner, and
the second ring reflector comprises material selected from opaque quartz or silicon-carbide (SiC) coated graphite.

9. A processing chamber, comprising:
a housing structure having a first side wall and a second side wall opposite the first side wall in a first direction;
a gas injection assembly coupled to the first side wall;
a gas exhaust assembly coupled to the second side wall;
a quartz chamber disposed within the housing structure;
a process kit disposed within the quartz chamber, the process kit comprising a cassette having a plurality of shelves configured to retain a plurality of substrates thereon;
a plurality of upper lamp modules disposed on a first side of the quartz chamber and configured to provide radiative heat to the plurality of substrates;
a plurality of lower lamp modules disposed on a second side of the quartz chamber opposite the first side in a second direction perpendicular to the first direction and configured to provide radiative heat to the plurality of substrates; and
a lift-rotation mechanism configured to move the cassette in the second direction and rotate the cassette about the second direction,
wherein the process kit further comprises:
an inner liner having:
a plurality of first inlet holes disposed on an injection side of the inner liner and configured to be in fluid communication with the gas injection assembly; and
a plurality of first outlet holes disposed on an exhaust side of the inner liner and configured to be in fluid communication with the gas exhaust assembly;
a top plate and a bottom plate attached to an inner surface of the inner liner, the top plate and the bottom plate forming an enclosure together with the inner liner, the cassette being disposed within the enclosure;
a first ring reflector disposed outside of the inner liner; and
an edge temperature correcting element disposed between the inner liner and the first ring reflector.

10. The processing chamber of claim 9, wherein
the process kit further comprises an outer liner, and
the outer liner comprises material selected from opaque quartz and silicon-carbide (SiC) coated graphite.

11. The processing chamber of claim 9, wherein
the inner liner comprises material selected from clear quartz and silicon-carbide (SiC) coated graphite,
the top plate and the bottom plate comprise material selected from clear quartz, opaque quarts, silicon-carbide (SiC) coated graphite,
the first ring reflector comprises material selected from opaque quartz or silicon-carbide (SiC) coated graphite, and
the plurality of shelves comprises silicon-carbide (SiC) coated graphite.

12. The processing chamber of claim 9, wherein the edge temperature correcting element comprises two graphite heaters surrounding the inner liner.

13. The processing chamber of claim 9, wherein the edge temperature correcting element comprises a lamp between the inner liner and the first ring reflector.

14. The processing chamber of claim 9, wherein the edge temperature correcting element comprises a toroidal lamp encircling the inner liner.

15. The processing chamber of claim 9, wherein
the edge temperature correcting element comprises a second ring reflector surrounding the inner liner, and
the second ring reflector comprises material selected from opaque quartz or silicon-carbide (SiC) coated graphite.

16. A processing system comprising:
a processing chamber comprising:
a housing structure having a first side wall and a second side wall opposite the first side wall in a first direction;
a gas injection assembly coupled to the first side wall;
a gas exhaust assembly coupled to the second side wall;
a quartz chamber disposed within the housing structure;
a process kit disposed within the quartz chamber, the process kit comprising:
a cassette having a plurality of shelves configured to retain a plurality of substrates thereon;
an inner liner having:
a plurality of first inlet holes disposed on an injection side of the inner liner and configured to be in fluid communication with the gas injection assembly; and
a plurality of first outlet holes disposed on an exhaust side of the inner liner and configured to be in fluid communication with the gas exhaust assembly; and
a top plate and a bottom plate attached to an inner surface of the inner liner, the top plate and the bottom plate forming an enclosure together with the inner liner, the cassette being disposed within the enclosure;
a first ring reflector disposed outside of the inner liner; and
an edge temperature correcting element disposed between the inner liner and the first ring reflector;
a plurality of upper lamp modules disposed on a first side of the quartz chamber and configured to provide radiative heat to the plurality of substrates;
a plurality of lower lamp modules disposed on a second side of the quartz chamber opposite the first side in a second direction perpendicular to the first direction and configured to provide radiative heat to the plurality of substrates;
a lift-rotation mechanism configured to move the cassette in the second direction and rotate the cassette about the second direction; and
a transfer robot configured to transfer the plurality of substrates into and from the process kit disposed in the processing chamber.

17. The processing system of claim 16, wherein
the process kit further comprises an outer liner outside of the first ring reflector, and
the outer liner comprises material selected from opaque quartz and silicon-carbide (SiC) coated graphite.

18. The processing system of claim 16, wherein
the inner liner comprises material selected from clear quartz and silicon-carbide (SiC) coated graphite,
the first ring reflector comprises material selected from opaque quartz or silicon-carbide (SiC) coated graphite, and
the plurality of shelves comprises silicon-carbide (SiC) coated graphite.

19. The processing system of claim 16, wherein the edge temperature correcting element comprises two graphite heaters surrounding the inner liner.

20. The processing system of claim 16, wherein the edge temperature correcting element comprises a lamp between the inner liner and the first ring reflector.

21. The processing system of claim 16, wherein the edge temperature correcting element comprises a toroidal lamp encircling the inner liner.

22. The processing system of claim 16, wherein
the edge temperature correcting element comprises a second ring reflector surrounding the inner liner, and
the second ring reflector comprises material selected from opaque quartz or silicon-carbide (SiC) coated graphite.
